(19) United States
(12) Patent Application Publication
(10) Pub. No.: US 2025/0202193 A1
(43) Pub. Date: Jun. 19, 2025

(54) CAVITY DESIGN FOR MULTI-WAVELENGTH LASERS

(71) Applicant: Quintessent Inc., Goleta, CA (US)

(72) Inventor: Michael DAVENPORT, Goleta, CA (US)

(21) Appl. No.: 19/056,184

(22) Filed: Feb. 18, 2025

Related U.S. Application Data
(63) Continuation-in-part of application No. 17/465,403, filed on Sep. 2, 2021.
(60) Provisional application No. 63/556,069, filed on Feb. 21, 2024.

(51) Int. Cl. H01S 5/0625; H01S 5/12

(52) U.S. Cl. CPC H01S 5/06258; H01S 5/1209; H01S 5/1228; H01S 5/124

(57) ABSTRACT

A photonic element includes a bottom cladding, a top cladding and a first waveguide that is located between the bottom and top claddings. A first multi-wavelength grating is optically coupled with the first waveguide. The multi-wavelength grating is characterized by a grating strength that varies along a first axis based on a piecewise mathematical function. The first waveguide and the multi-wavelength grating collectively enable an output having a plurality of wavelengths.

### CROSS REFERENCE TO RELATED APPLICATION

This application claims the benefit of U.S. Provisional application No. 63/556,069, filed Feb. 21, 2024, the contents of which are incorporated herein by reference.

This application is a continuation-in-part of U.S. application Ser. No. 17/465,403, filed Sep. 2, 2021, which is incorporated by reference in its entirety.

### TECHNICAL FIELD

The present disclosure related to photonic elements in general, and more particularly to distributed-feedback reflector-based photonic elements.

### BACKGROUND

The windowed sampled grating (WSG) is a modified type of Bragg grating suitable for producing multiple optical wavelengths. The grating strength (which is defined as the difference in the effective refractive index between the grating elements and the gap sections) of the WSG varies according to a desired function along the longitudinal axis of the device to enable a multi-wavelength output. In other words, the reflectivity of the grating elements (i.e., the effective refractive-index contrast at the grating elements) varies along the longitudinal axis of the grating according to a desired function. The refractive index profile of the WSG can be specifically tailored to produce resonance and therefore high reflection at a specific set of wavelengths. For example, the WSG may be designed to produce 16 wavelengths spaced apart by 1 nm, centered around 1310 nm. In contrast to a WSG, a conventional Bragg grating produces a reflection at a single wavelength, and a sampled grating produces a series of reflection peaks which are uniformly spaced in wavelength and have an amplitude profile that is fixed by the sampling function.

Examples of WSGs and illustrative methods of physically implementing them to produce the desired refractive index profile may be found in co-pending U.S. application Ser. No. 17/465,403, entitled “Windowed Sampled Grating and Method of Fabrication.”

WSGs may be used in a number of different applications. For example, they may be used in passive waveguide systems, in combination with gain media to realize multi-wavelength lasers, as sources for providing wavelength “combs,” as multi-wavelength filters, and the like. A multi-wavelength laser lases at the set of wavelengths that is defined by the WSG, much like conventional single-wavelength lasers based on distributed Bragg reflectors. The grating can be fully passive and placed outside of the amplifier section, forming the laser cavity between the grating and a back mirror, which may be another WSG or a broadband reflector such as a facet, or it can be contained inside the amplifier section, such as in a distributed-feedback (DFB) laser. In a DFB laser the grating extends within the laser cavity to provide optical feedback that results in a narrow linewidth output. The DFB configuration is desirable because there is no need to align the phase of the cavity mode with the grating passband, as must be done in the case where the grating is a separate section from the amplifier.

DFB lasers with gratings designed to reflect at a single wavelength are well known to lase at two wavelengths on either side of the grating stop band unless the grating is engineered to include a resonant cavity. Since it is often desirable for the laser to lase at a single wavelength, various methods have been developed to produce only a single wavelength. The most prevalent method is to introduce a quarter-wave phase shift into the grating. For instance, the grating may have a section at its center that introduces the extra quarter-wave phase shift combined with low reflection facets. Such DFB lasers are typically referred to as quarter-wave shifted DFB lasers. Alternatively, the grating may be cleaved in half and provided with a high reflection coating on one side, which produces an effect similar to that which would be created by a quarter-wavelength phase shift section of grating that lays across the high reflection coated cleaved facet. These DFB lasers are typically referred to as high reflection/low reflection facet lasers, often denoted as HR/AR lasers.

While the HR/AR DFB laser can be more efficient and simpler to produce than the quarter-wave shifted DFB laser, the HR/AR laser suffers from low yield due to the practical impossibility of cleaving perfectly on the edge of the final grating tooth. While it is theoretically possible to produce an HR/AR that incorporates a WSG, it is unlikely that the multiple lasing wavelengths of the laser will behave correctly with a random phase error on the HR facet. This will make high yield production difficult if not virtually impossible.

Unfortunately, the quarter-wave shifted DFB laser has well known drawbacks. Two principal difficulties with this design are spatial hole burning, which limits the optical linewidth and maximum output power, and reduced efficiency due to wasted power emitted from the anti-reflection coated backside. Spatial hole burning can be addressed by employing a “corrugation pitch modulation” (CPM) cavity design, where the λ/4 section is replaced by longer section of grating with a slightly different pitch from the main DFB grating. The backside power emission can be reduced by placing the cavity asymmetrically inside the grating.

Accordingly, it would be desirable to provide multi-wavelength photonic elements that incorporate a quarter-wave shift and which can be used, for example, to provide a quarter-wavelength shifted multi-wavelength DFB laser.

### SUMMARY

In one aspect, the present disclosure is directed toward multi-wavelength gratings suitable for providing multiple wavelength signals that propagate in a waveguide, as well as multi-wavelength lasers that incorporate them. Devices in accordance with the present disclosure include a multi-wavelength grating whose grating strength and/or phase varies according to a desired piecewise mathematical function along the longitudinal axis of the device to enable a multi-wavelength output signal. In other words, the reflectivity of the grating elements (i.e., the effective refractive-index contrast at the grating elements) and, in some cases, the grating pitch, varies along the longitudinal axis of the grating according to a desired piecewise mathematical function. As a result, an optical signal propagating through the grating sees a variation of the reflection strength at the transitions between the grating element and the gap material between them as it traverses the grating. Embodiments in accordance with the present disclosure are particularly well suited for use in passive waveguide systems, in combination with gain media to realize multi-wavelength lasers, as sources for providing wavelength “combs,” as multi-wavelength filters, and the like.

An embodiment in accordance with the present disclosure is a photonic element comprising: a bottom cladding; a top cladding; a first waveguide that is located between the bottom and top claddings; and a first multi-wavelength grating that is optically coupled with the first waveguide, wherein the multi-wavelength grating is characterized by a grating strength that varies along a first axis based on a piecewise mathematical function; wherein the first waveguide and the multi-wavelength grating collectively enable an output having a plurality of wavelength.

In some embodiments, the first multi-wavelength grating is a windowed sampled grating (WSG). In other embodiments the first multi-wavelength grating is a binary superimposed grating (BSG) or a phase grating (PG).

In some embodiments a quarter-wave phase shift is introduced into the first multi-wavelength grating. In some embodiments the quarter-wave phase shift is introduced by incorporating a corrugation pitch modulated (CPM) grating section into the multi-wavelength grating.

In some embodiments, the first multi-wavelength grating has a plurality of grating sections each characterized by a grating strength that varies along the first axis based on a subfunction of the piecewise mathematical function for each different one of the wavelengths. Each of the subfunctions is defined as a summation, over the plurality of wavelengths, of an expression that represents a grating at a single wavelength defined in the expression.

In another aspect, the present disclosure is directed toward a multi-wavelength DFB laser that includes an active layer and grating-element layer that are collectively located between upper and lower cladding layers. A multi-wavelength grating is formed in the grating-element layer, which is optically coupled with a gain layer such that the multi-wavelength grating functions as a mirror of the laser cavity. The grating-element layer is located between the active layer structure and its upper or lower cladding structure. In one particular embodiment, the grating is located below the active layer. The grating elements of the multi-wavelength grating are openings in the grating-element layer, where a lithographically defined feature of the grating elements such as their width varies along the longitudinal axis according to a piecewise mathematical function. The effective index contrast and, therefore, the effective reflectivity at each grating element is based on the value of its width or other lithographically defined feature.

The multi-wavelength DFB laser in accordance with the present disclosure can be designed to lase at the intended wavelengths, with high efficiency, high output power, and high directivity, where high directivity refers to the ability to direct the emitted output power in a desired direction. The cavity of the multi-wavelength DFB laser is also able to support an arbitrary channel plan.

In addition, the multi-wavelength DFB laser in accordance with the present disclosure can scale with the number of emission wavelengths without necessarily affecting the size of the laser. Also, because the grating in a WSG has a comparatively unform pitch and effective refractive index, there is no unintended feedback from one wavelength into the other. Further, since the cavities of the laser can be overlaid on each other, the impact of spatial hole burning can be equalized.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 depicts a schematic drawing of a plan view of a portion of an exemplary WSG in accordance with the present disclosure.

FIG. 2 is an example of four piecewise sinusoidal refractive index profiles for a multi-wavelength grating of length L with a phase shift in the center.

FIG. 3 shows the WSG waveform that results from the summation of the sinusoidal refractive index profiles shown in FIG. 2.

FIG. 4 shows four single-wavelength piecewise sinusoidal refractive index profiles similar to those shown in FIG. 2, but with a central section between L₁ and L₂ having a higher pitch than the other sections of the grating.

FIG. 5 shows the full analog waveform that arises from the summation of the piecewise sinusoidal functions shown in FIG. 4.

FIG. 6 illustrates the cold cavity reflection spectrum of one example of a practical multi-wavelength CPM DFB laser.

FIG. 7 shows the analog refractive index profile of the WSG for the laser of FIG. 6.

FIG. 8 shows the refractive index profile of a four-channel multi-wavelength CPM DFB laser with a single wavelength CPM section forming the cavity.

FIG. 9 shows the resulting cold cavity reflection spectrum for the CPM DFB laser of FIG. 8

FIG. 10 shows the analog waveform for a WSG with a CPM cavity designed with non-uniform optical frequency spacing.

FIG. 11A shows a schematic drawing of a plan view of an illustrative embodiment of a portion of a laser comprising a WSG in accordance with the present disclosure.

FIGS. 11B and 11C show schematic drawings of cross-sectional views of the laser in FIG. 11A depicting representative examples of a grating element and gap, respectively.

FIG. 12A is a plan view of another example of a multi-wavelength CPM DFB laser.

FIGS. 12B and 12C are cross-sectional views of the laser of FIG. 12A taken along lines b-b and c-c in FIG. 12A, respectively.

### DETAILED DESCRIPTION

A windowed sampled grating (WSG) is a specially modified Bragg grating in which the grating strength (defined by the difference in effective refractive-index between the grating elements and gap sections between them) has a desired non-uniform profile along the propagation direction inside the grating. In some embodiments, the grating pitch varies along the propagation direction. This grating-strength and phase profile is specifically tailored to produce resonance and therefore high reflection at a specific set of wavelengths.

A WSG enables the creation of an intra-cavity filter with an emission spectrum that is custom tailored for applications requiring multiple wavelengths (also referred to as “wavelength signals”), such as wavelength-division multiplexed systems. This emission spectrum will then be stable with respect to changes in temperature, allowing uncooled operation, as the number of lasing modes will not change with temperature and the pattern will drift with temperature due to the thermo-optic effect (0.1 nm/C) instead of the band gap shrinkage effect (0.5 nm/C). In addition, a WSG enables the creation of custom and arbitrary wavelength grids to satisfy any of a wide range of WDM system requirements. It is capable of producing widely spaced grids for coarse wavelength division multiplexed (CWDM) systems, as well as tightly spaced grids for dense wavelength division multiplexing (DWDM) and anything in between. The gratings can be used in lasers to form distributed feedback (DFB) lasers.

As described in co-pending U.S. application Ser. No. 17/465,403, a WSG can be described by an analog refractive index profile as a function of length along the grating. The refractive index profile n can be expressed by equations 1-6 as follows:

$$\begin{matrix}1. & n ( l ) = {n}_{eff +} W ( l ) {\sum }_{i = 0}^{N} Δ {n}_{i} sin ( \frac{2 π l}{{Λ}_{i}} + {ϕ}_{i} ) \\ 2. & Δ {n}_{i} = [ Δ {n}_{0} , Δ {n}_{1} , Δ {n}_{2} , … Δ {n}_{0} ] \\ 3. & {Λ}_{i} = [ {Λ}_{0} , {Λ}_{1} , {Λ}_{2} , … {Λ}_{N} ] \\ 4. & {ϕ}_{i} = [ {ϕ}_{0} , {ϕ}_{1} , {ϕ}_{2} , … {ϕ}_{N} ] \\ 5. & {λ}_{i} = [ {λ}_{0} , {λ}_{1} , {λ}_{2} , … {λ}_{N} ] \\ 6. & {Λ}_{i} = \frac{{λ}_{i}}{2 {n}_{eff}}\end{matrix}$$

where N is the number of wavelength reflections such that in equation 1 the refractive index profile n is defined by the summation of N sinusoidal refractive index profiles. Each sinusoid has a refractive index amplitude of Ani, which is a set defined by Equation 2, and a pitch defined by Λᵢ, which is a set defined by Equation 3, and a set of phases φᵢ defined by Equation 4. The pitch is derived from the desired emission wavelengths λᵢ, which is a set defined by Equation 5, by using the formula given by equation 6. W(l) is a window function, such as a Blackman or Tukey window, which may be applied to the waveform to reduce the appearance of side lobes. W(l) may also be equal to 1. The summation of sinusoidal refractive index profiles is then added to the waveguide effective index, n_{eff}, as an index perturbation.

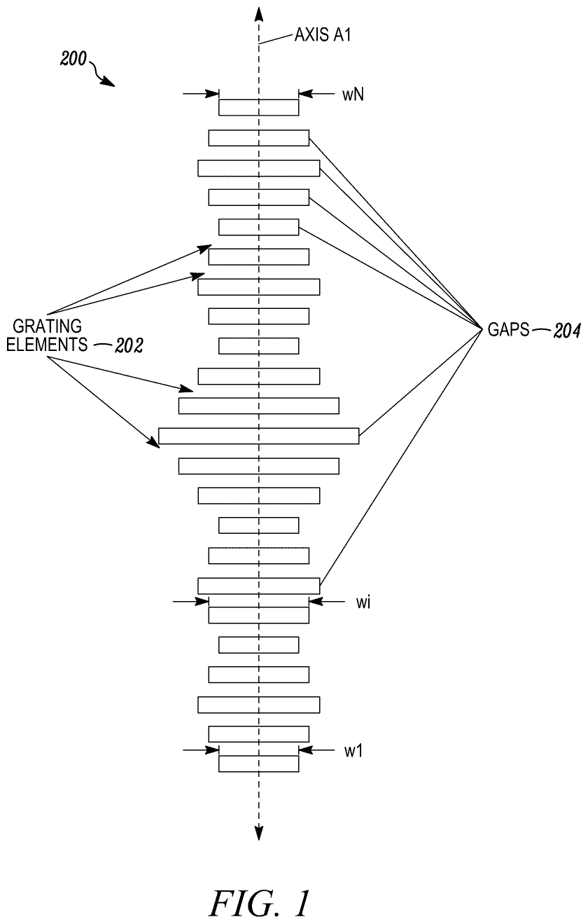

FIG. 1 depicts a schematic drawing of a plan view of a portion of an exemplary WSG in accordance with the present disclosure. Grating 200 includes a series of grating elements 202-1 through 202-N that are separated by gaps 204-1 through 204-N, respectively. Grating elements 202-1 through 202-N (referred to, collectively, as grating elements 202) are arranged along longitudinal axis A1 and configured such that the grating strength varies nonlinearly along axis A1 in substantially smooth fashion. Typically, grating elements 202 and gaps 204 are formed in a waveguide layer or a grating-element (GE) layer that is operatively coupled with a waveguide layer and/or an active layer configured to provide optical gain (to collectively define a WSG laser).

Grating elements 202 and gaps 204 can be formed in many well-known ways, such as by forming features in a suitable material layer, where each of the features is configured to define its desired reflectivity. As will be apparent to one skilled in the art, the reflectivity of a grating feature can be controlled by controlling at least one of feature width, feature depth, gap distance, including structures located adjacent to each grating element, and the like. Examples of structures that give rise to a variation in the effective refractive index along a waveguide are described in co-pending U.S. application Ser. No. 17/465,403.

In the depicted example, grating strength at each grating element 202-i, where i=1 through N, is determined by the width, w(i), of that grating element and defined by its adjacent gap 204i, which varies along longitudinal axis A1 according to a sinc function convolved with an infinite sampling function in the length domain. It should be noted, however, that myriad grating-strength variations are within the scope of the present disclosure including, without limitation, sinusoidal functions, sums of sinusoidal functions, convolved sinusoidal and sinc functions, etc.

As previously mentioned, quarter-wave shifted DFB lasers that operate at a single wavelength are well known. In accordance with the present disclosure, a quarter-wave shifted DFB laser that operates at multiple wavelengths may be produced by inserting the phase shift into each of the individual sinusoidal index profiles of Equation 1 at a certain position along the longitudinal axis of the WSG, Lₛ. At this position, the N sinusoidal refractive index profiles of Equation 1 now each represent a subfunction of a piecewise function, where each subfunction of the piecewise function is a WSG representing a portion of the overall grating. The subfunction for Lₛ<l<L is uniformly shifted in phase by θₛ.

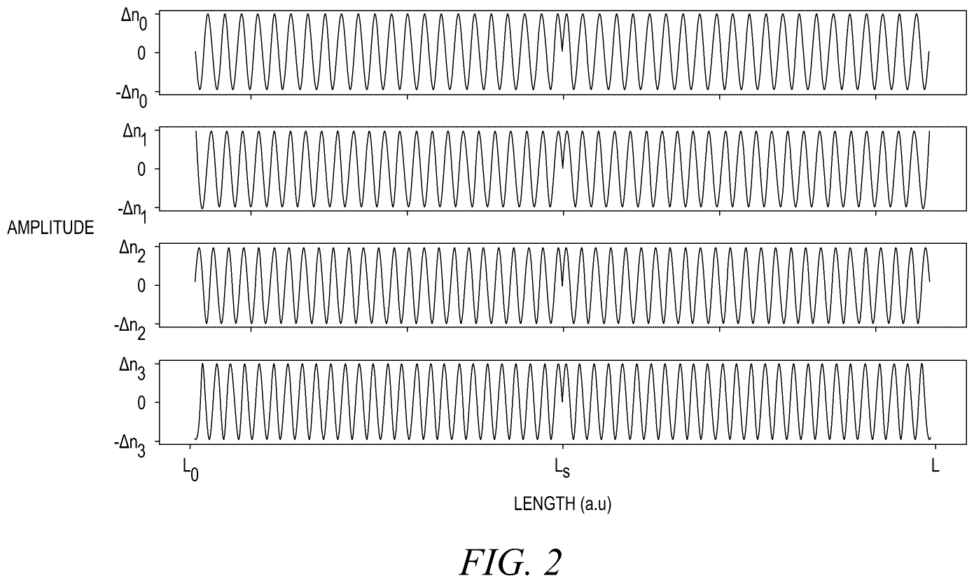

An example of four sinusoidal refractive index profiles for a grating of length L with a phase shift in the center of each is shown in FIG. 2. The expressions can then be summed to produce the quarter wave shifted WSG function. This is expressed mathematically in Equation 7 as:

$$7. n ( l ) = {n}_{eff +} W ( l ) \{ \begin{matrix}{\sum }_{i = 0}^{N} Δ {n}_{i} sin ( \frac{2 π l}{{Λ}_{i}} + {ϕ}_{i} ) , & {L}_{0} < l < {L}_{s} \\ {\sum }_{i = 0}^{N} Δ {n}_{i} sin ( \frac{2 π l}{{Λ}_{i}} + {ϕ}_{i} + {θ}_{s} ) , & {L}_{s} < l < L\end{matrix}$$

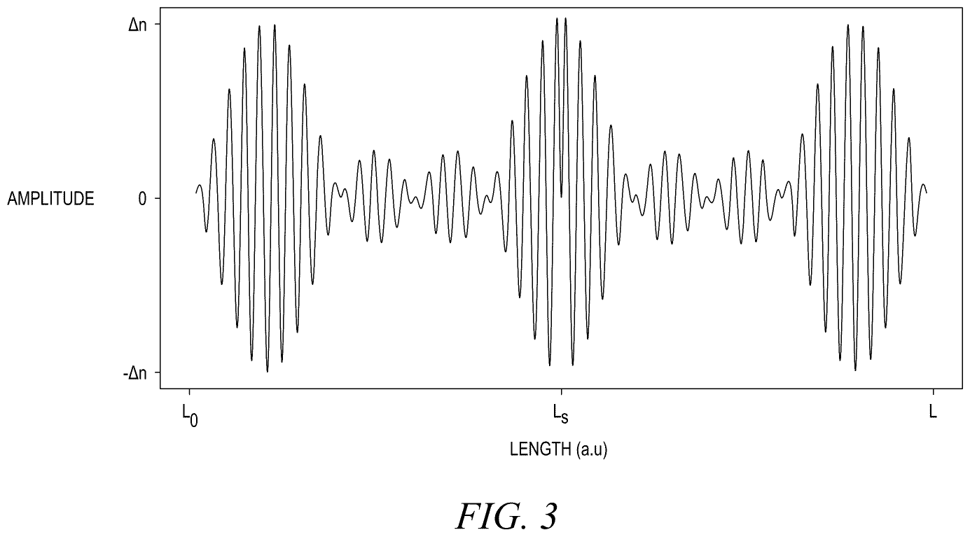

Equation 7 is in principle similar to Equation 1, except now it is a piecewise formula that is used to define different sections of the grating. After a certain length Lₛ along the grating, an additional θₛ phase shift is added to the sinusoid. Typically, θₛ is π/2, but it is not limited to this value; some design-for-manufacturing constraints might require θₛ to be an integer multiple of π/2, for example. Note that the phase shift may be placed asymmetrically if desired to improve the directivity. FIG. 3 shows the WSG waveform that results from the summation of the sinusoidal refractive index profiles shown in FIG. 2. Note that the waveforms shown in FIGS. 2 and 3 are much shorter and have wider wavelength spacing than a practical WSG DFB laser. They are displayed in this form so that the phase shift will be visible compared to the rest of the grating.

As previously mentioned, quarter wave shifted single-wavelength DFB lasers suffer from spatial hole burning, which results from high power buildup in the vicinity of the phase shift. Spatial hole burning increases the optical linewidth and increases the likelihood of longitudinal multimoding at high current bias. The impact of spatial hole burning can be mitigated by replacing the phase shift with a distributed phase shift in the form of a section of grating that has a slightly different pitch than the majority of the laser. This essentially increases the size of the laser cavity from one half of a grating pitch to several tens of micrometers, greatly reducing the concentration of optical power and thereby reducing the impact of spatial hole burning. A grating section that has such a distributed phase shift is referred to as a corrugation pitch modulated (CPM) grating section, and is discussed in Makoto Okai et al. 1994 Jpn. J. Appl. Phys. 33 2563, which is hereby incorporated by reference in its entirety.

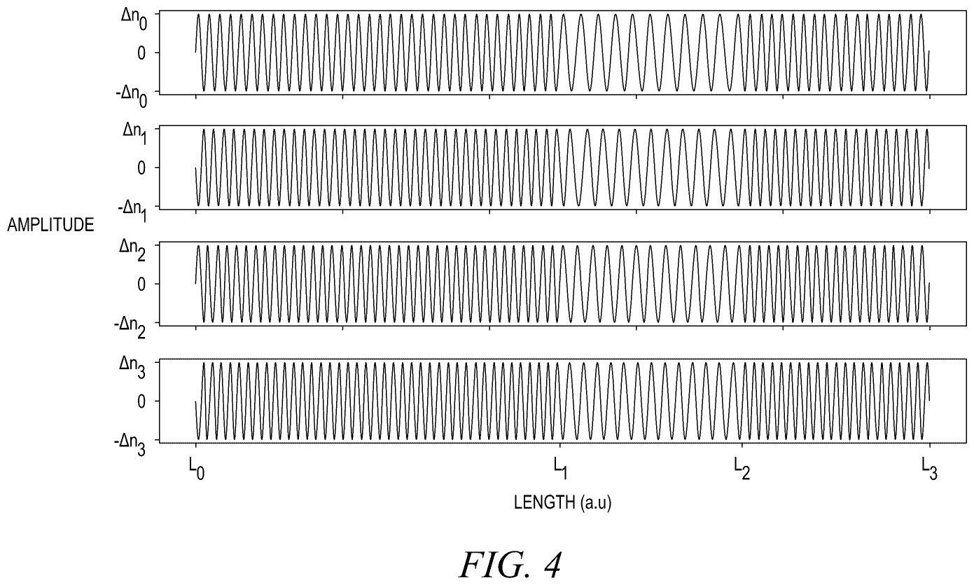

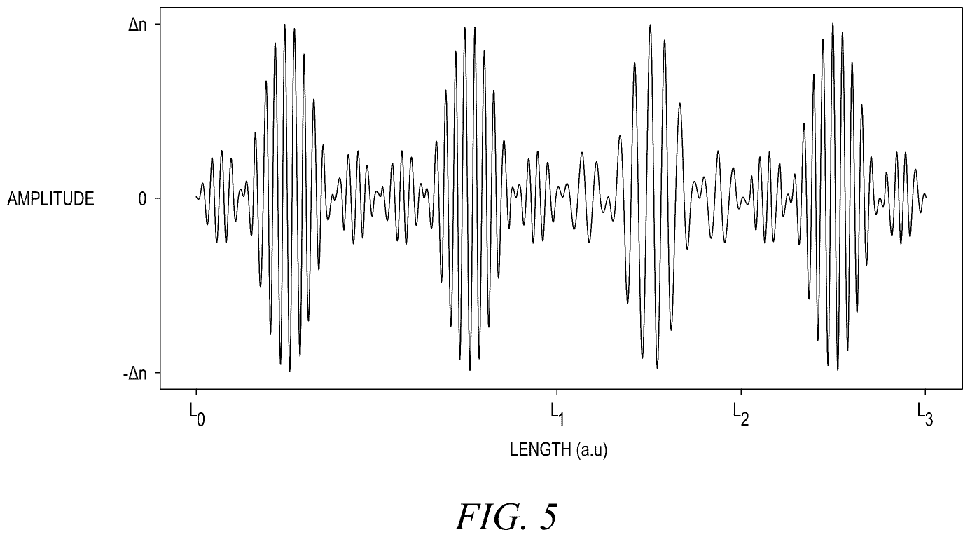

The use of a CPM grating section can be extended to multi-wavelength DFB lasers to provide a multi-wavelength CPM DFB laser. FIG. 4 shows four single-wavelength piecewise sinusoidal refractive index profiles similar to those shown in FIG. 2, but with a central section between L₁ and L₂ having a higher pitch than the other sections of the grating. These sinusoidal functions taken individually represent examples of a CPM DFB laser. Summation of the waveforms represented by these functions results in a WSG with a central CPM grating section that has a higher pitch. FIG. 5 shows the full analog waveform that arises from the summation of the piecewise sinusoidal functions shown in FIG. 4. As above for the quarter wave shifted DFB, the length and wavelength spacing of this WSG have been selected for clarity of illustration and does not necessarily represent a practical embodiment. These gratings have the mathematical form shown in Equation 8:

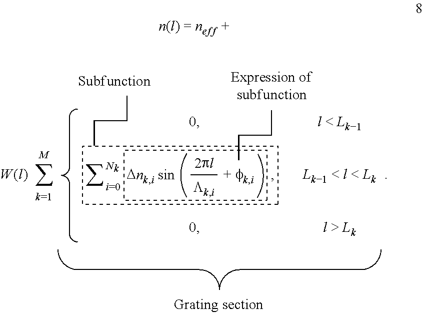

Equation 8 is a finite sum of piecewise formulae representing the individual grating sections of the WSG. The grating has M sections, and each Δn_{k,i}, Λ_{k,i}, φ_{k,i} may be different sets of values for each k. Each grating section k is characterized by Nₖ subfunctions, where each subfunction is defined as a summation over the wavelengths of a sinusoidal expression that represents a grating at a single wavelength defined in the expression by Equation 6. In addition, the sections need not have the same number of wavelength channels, as N, which was formerly an integer in Equations 1 and 7, is now a set containing k values. The example in FIGS. 4 and 5 has k=3, and the sets Δn_{k,i}, Λ_{k,i}, φ_{k,I} are identical for all three sections except Λ_{2,i}, the values for the Bragg wavelengths in section 2, which have been increased. Note that in this example L₁−L₀>L₃−L₂. That is, the CPM section is asymmetrically positioned in the WSG. The longer grating section between L₀ and L₁ increases the reflection strength of this section, thereby directing more output power to the L₃ side of the multi-wavelength CPM DFB laser. In other embodiments the different grating sections may have different lengths and the CPM section may be distributed symmetrically or asymmetrically in the WSG.

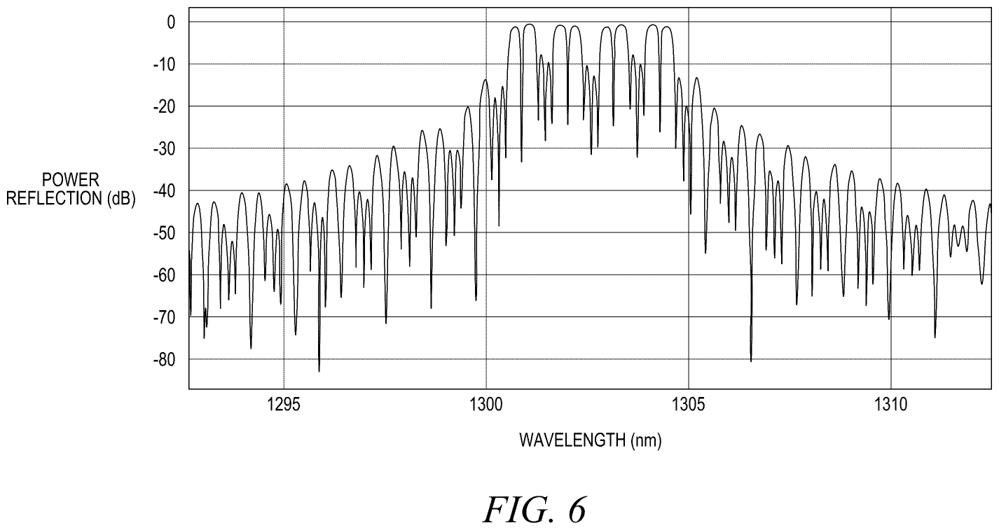

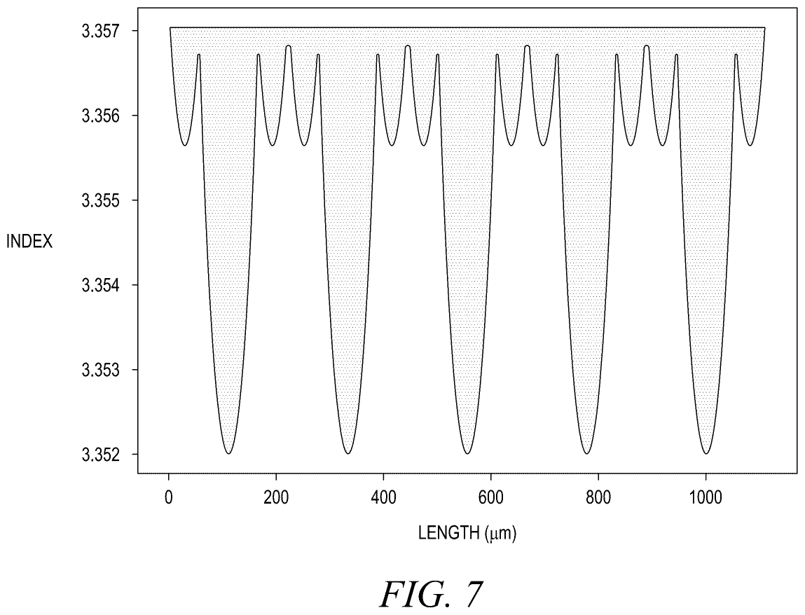

FIG. 6 illustrates the cold cavity reflection spectrum of one example of a practical multi-wavelength CPM DFB laser. This device has 4 emission wavelengths spaced by 1 nm, which can be seen by the four characteristic stop bands with a central notch between 1300 and 1305 nm. The analog refractive index profile of this WSG for this laser is shown in FIG. 7. In this example the refractive index profile has been flattened to allow for the production of a semiconductor multi-wavelength CPM DFB laser using the techniques illustrated in previously mentioned U.S. application Ser. No. 17/465,403. While it cannot be easily seen in FIG. 7 due to the scale of the cavity compared to the pitch and the lower relative difference in pitch between the WPM and WSG sections, the central group of 3 peaks in the refractive index profile have a grating pitch corresponding to a center wavelength of 1335 nm, while the rest of the grating has a grating pitch corresponding to a center wavelength of 1302.5 nm.

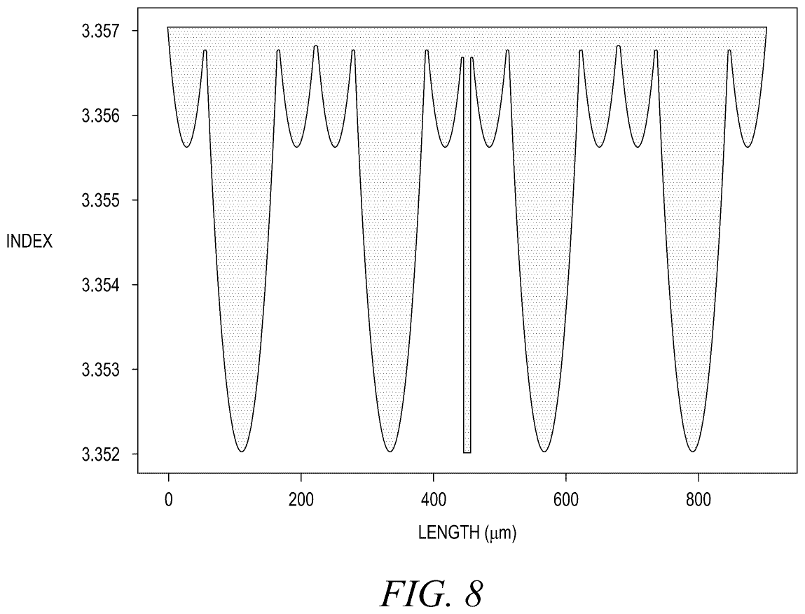

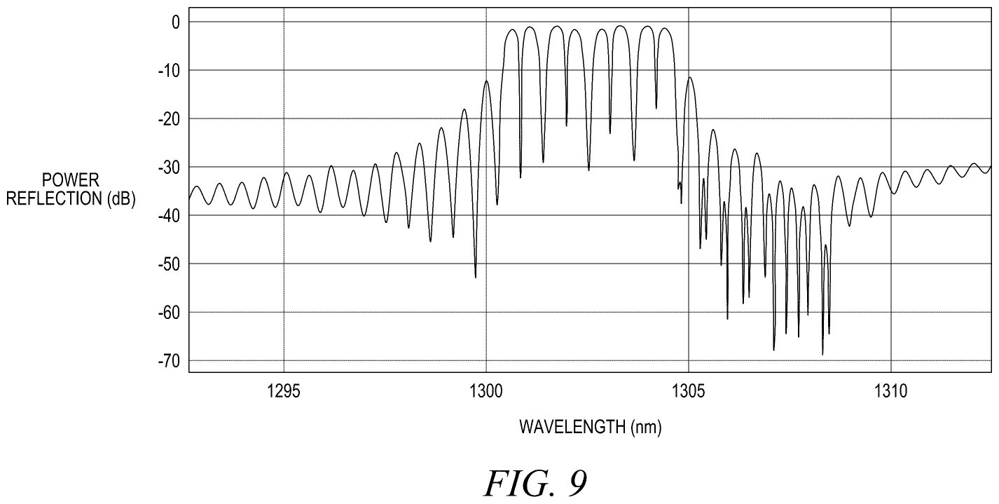

Another example of a multi-wavelength CPM DFB laser employs a WSG that has a refractive index profile that is represented by a special case of Equation 8 when N₂, the number of piecewise functions in the central cavity section, only has a length of 1. That is, there is a simple harmonic grating in the cavity section. The refractive index profile of this grating, which is shown in FIG. 8, is otherwise similar to the grating in FIG. 7, except it has a single wavelength grating section as the cavity. This cavity section needs to be detuned from the wavelengths in the comb and needs to have a particular length to accumulate a π/2, or an integer multiple thereof, phase shift. The resulting cold cavity reflection spectrum of this laser is shown in FIG. 9. Once again, four stop band sections with central defects are shown. This grating has the advantage of a simpler design and fabrication compared to the WSG in FIG. 7, but the single wavelength CPM section is not as long as the CPM section in FIG. 7 before the cavity begins to dephase with the stop bands across the grid. This can be seen as an advantage, since the multi-wavelength CPM DFB laser will be more compact, or as a disadvantage, because the optical power will be more concentrated in the shorter CPM section.

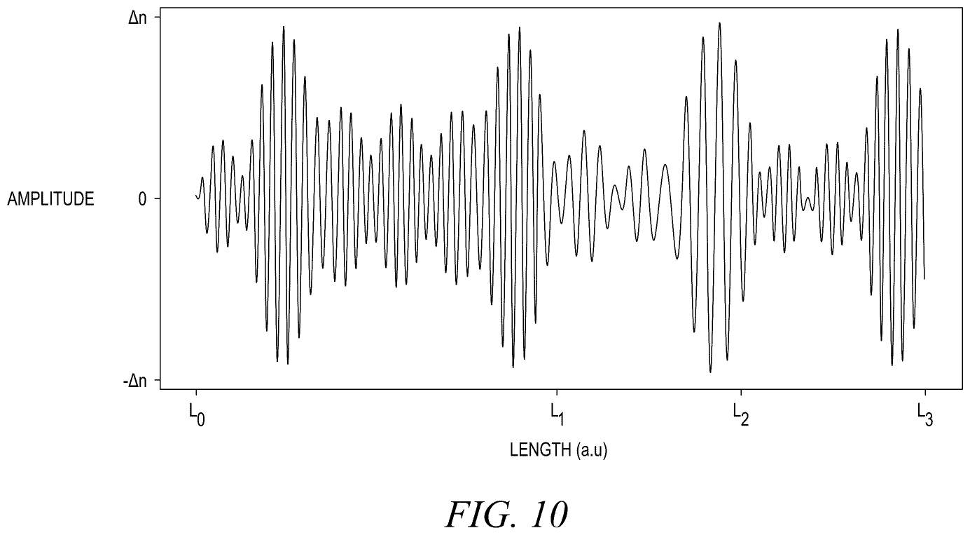

FIG. 5 shows another example of a full analog waveform for a WSG, which has an orderly set of super-periods, two at the pitch of the reflector sections between L₀ and L₁, one at the pitch of the CPM section between L₁ and L₂, and another at the pitch of the reflector section between L₂ and L₃. The existence of these super periods is related to the wavelength spacing in the comb of wavelengths reflected by the grating. If the optical frequency spacing in the comb is uniform, the grating will assume the appearance of super periods. While a uniformly spaced comb is one potential application, it may be desirable to have a non-uniformly spaced comb, for example, to suppress four-wave mixing, or to have discrete groups of wavelengths. In this case, the super periods will not appear and the grating may take on a more disorderly appearance, as shown in FIG. 10.

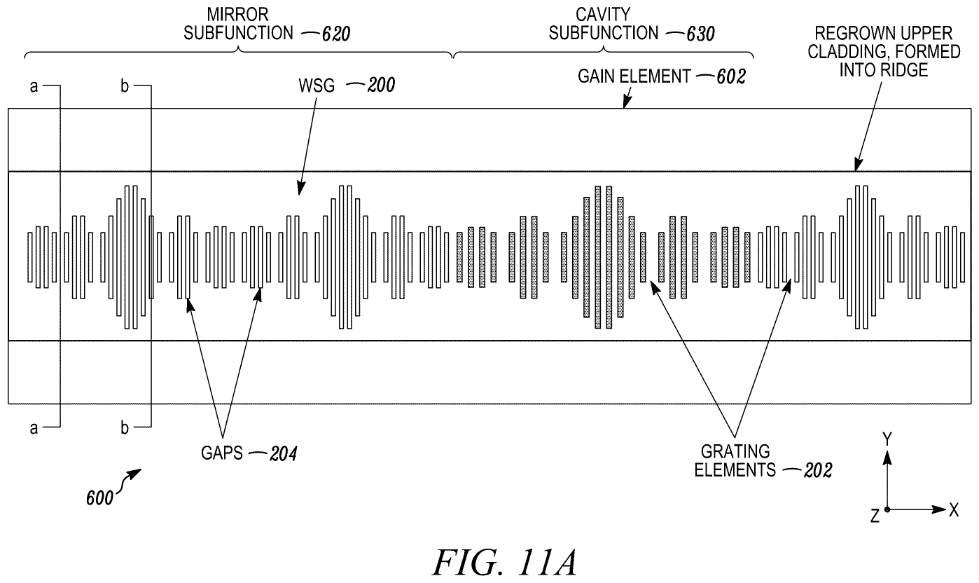

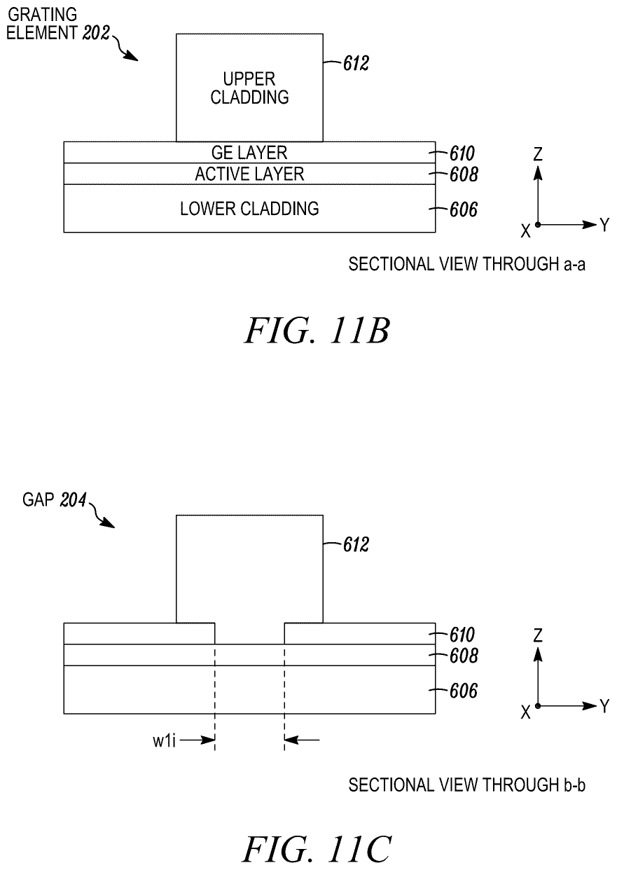

FIG. 11A shows a schematic drawing of a plan view of an illustrative embodiment of a portion of a laser comprising a WSG in accordance with the present disclosure. Laser 600 comprises gain element 602 and WSG 200, which are optically coupled to collectively define a multi-wavelength CPM DFB laser structure. The grating structure of WSG 200 includes grating elements 202 and gaps 204, which are configured to define a waveguide-based grating whose refractive index varies along longitudinal axis x according to a piecewise mathematical function.

WSG 200 corresponds to the analog waveform shown in FIG. 5. As shown in FIG. 6A, WSG 200 includes a section that represents mirror subfunction 620 and cavity subfunction 630.

FIGS. 11B and 11C show schematic drawings of cross-sectional views of the laser structure of laser 600 depicting representative examples of a grating element 202 and gap 204, respectively. FIGS. 11B and 11C are taken through lines a-a and b-b of FIG. 11A, respectively. As shown, the layer structure of laser 600 includes lower cladding 606, active layer 608, grating-element (GE) layer 610, and top cladding 612.

Lower cladding 606 is a conventional cladding layer suitable for inclusion in a DFB laser structure. In one example, lower cladding 606 may comprise aluminum gallium arsenide (AlGaAs) that is formed on a substrate (not shown) such as a conventional gallium arsenide (GaAs) substrate. Gain element 602 is defined by active layer 608, which may be, for example, a layer of GaAs comprising quantum elements (e.g., quantum dots, quantum dashes, quantum wells, etc.) such that active layer 608 enables optical gain. GE layer 610, which is formed on active layer 608, may be, for example, a layer of GaAs. The grating structure of WSG 200 may be formed in GE layer 610 by completely removing the layer in the gap regions to expose underlying active layer 608. In some embodiments, the grating structure of WSG 200 is formed by partially etching GE layer 610 in the gap regions.

Each of grating elements 202 includes a portion of GE layer 610 having its as-deposited thickness of t1. In other words, each of grating elements is an unetched portion of GE layer 610. In the depicted example, the refractive index of each grating element 202-i is based on its width, w1i, which is defined by the width of its corresponding adjacent gap 204-i. A substantially smoothly varying refractive-index profile along longitudinal axis A1 can be realized in accordance with the present disclosure because the refractive index at each grating element is based on a lithographically defined parameter of the grating element. Furthermore, although this parameter is the grating-element width in the depicted example, any suitable parameter variation can be used without departing from the scope of the present disclosure.

For example, in some embodiments, a smoothly varying refractive-index function is realized along longitudinal axis A1 by including features on either side of each grating element. The spacing between the structures and the grating elements determines the refractive index at each grating element and it is varied along the length of the grating to vary the refractive-index profile. Since this spacing is lithographically defined, it can be varied smoothly according to any desired piecewise mathematical function (e.g., sinusoids, sinc functions, combinations of sinusoids, combinations of sinusoids and sinc functions, etc.).

Upper cladding 612 is formed as a ridge structure on GE layer 610 via regrowth techniques. Upper cladding 606 is analogous to lower cladding 604 and, may comprise, for example, aluminum gallium arsenide (AlGaAs).

By varying the width (dimension along the y-axis as shown) or depth (dimension along the x-axis as shown) of this etched pattern, a WSG DBR or DFB is formed in which the grating elements of the grating are defined by the etched pattern. This type of waveguide may also be implemented in a fiber Bragg reflector, by varying the refractive index of the sections along the waveguide.

It should be noted that, although the depicted example includes a WSG formed in a grating-element layer included in a structure for this purpose, the inclusion of a grating-element layer is optional and a WSG can be realized in other layers of a structure without departing from the present disclosure. For example, in some embodiments, a WSG is at least partially formed in:
i. the top cladding layer of a structure; or
ii. a passive waveguide that is optically coupled with a structure; or
iii. the active layer of a structure; or
iv. any combination of i, ii, and iii.

As will be apparent to one skilled in the art, after reading this Specification, completion of a laser in accordance with the present disclosure typically includes several additional conventional operations, such as device singulation, formation of laser facets, and the like, which are not described herein. It should be noted, however, that one or both of the facets of a laser in accordance with the present disclosure can include additional material (e.g., a high-reflection layer, anti-reflection coating, etc.) as necessary to ensure laser emission at the intended wavelengths.

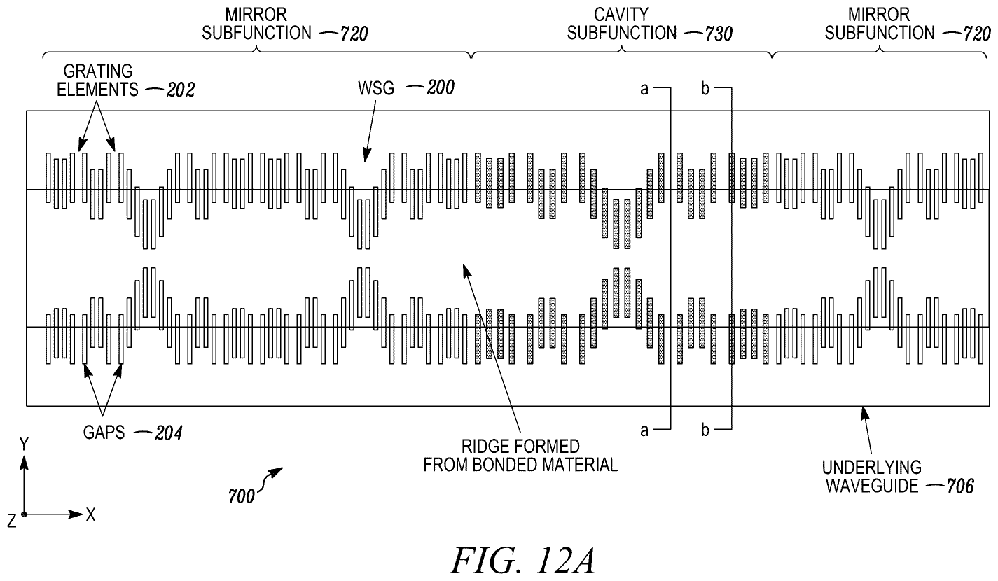

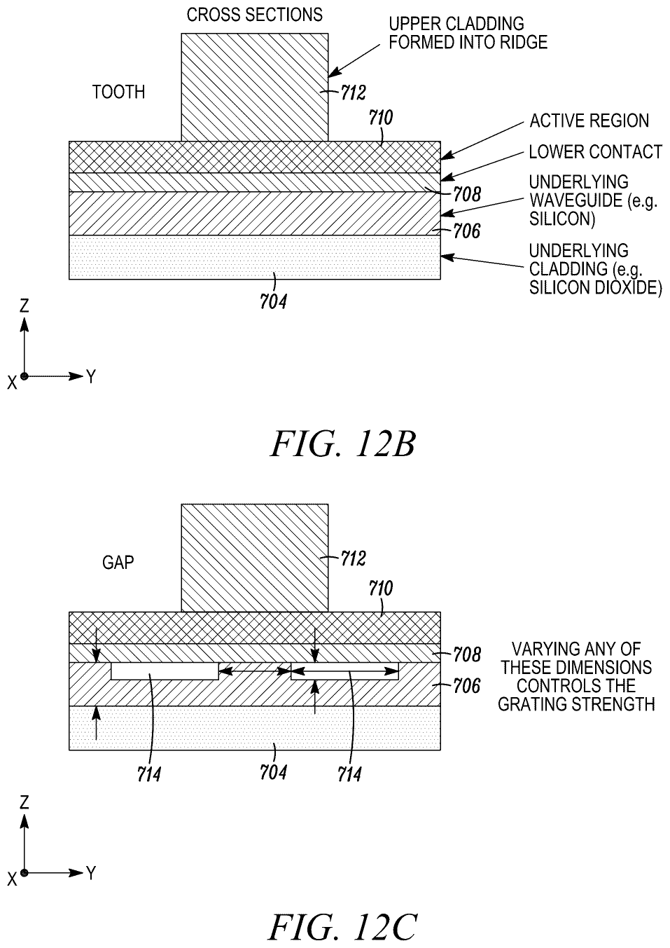

FIGS. 12A-12C show schematic drawings of another embodiment of a multi-wavelength CPM DFB laser 700 comprising a WSG 200 in accordance with the present disclosure. FIG. 12A is a plan view of the multi-wavelength CPM DFB laser 700. FIGS. 12B and 12C are schematic drawings of cross-sectional views of the laser structure of laser 700 taken along lines a-a and b-b in FIG. 12A, respectively. This embodiment is fabricated using hybrid integration techniques that avoid the need for epitaxial regrowth. WSG 200 includes grating elements 202 and gaps 204. WSG 200 includes sections that represent mirror subfunctions 720 and cavity subfunction 730. As explained below, hybrid integration is used to bond contact, cladding and active layers to a semiconductor waveguide after formation of the WSG 200 in the semiconductor waveguide.

As shown in the cross-section views, laser 700 comprises lower cladding 704, waveguide 706, contact layer 708, active layer 710, and upper cladding 712 that is defined as a ridge. Waveguide 706 is a layer of material suitable for conveying light generated by active layer 710. For example, in one embodiment waveguide 700 comprises silicon and the lower cladding layer comprises silicon dioxide. Waveguide 706 is optically coupled with active layer 710 via contact layer 708, which facilitates bonding between the waveguide material and the material of active layer 710.

The WSG 200 of laser 700 is formed by etching wells 714 in waveguide 706, where the effective index of refraction of a grating element is based on the values of the width and depth of each well 714, at least one of which is varied along the longitudinal axis of laser 700 according to a piecewise mathematical function (e.g., sinusoid, sinc, etc.) as discussed above.

Contact layer 708, active layer 710, and upper cladding 712 may be fabricated in a separate process by epitaxially growing the layers on a sacrificial substrate, after which they can be flipped over and bonded to the waveguide 706 using hybrid fabrication techniques such as direct bonding, plasma bonding, fusion bonding, thermo-anodic bonding, and the like.

It should be noted that, although many of the examples provided here are III-V semiconductor-based DFB laser waveguides, embodiments in accordance with the present disclosure can be formed in any waveguide platform suitable for the formation of Bragg gratings, such as silicon nitride waveguides, doped-silicon-dioxide core waveguides, passive silicon-on-insulator waveguides, thin-film filters, and the like. In addition, Bragg gratings can be present on both sides of laser gain material or on only one side (typically, with a different type of reflector on the other side) without departing from the scope of the present disclosure.

In the examples presented above the grating is described as a windowed sampled grating. More generally any suitable multi-wavelength grating may be employed. For example, instead of a windowed sampled grating, multi-wavelength gratings such as binary superimposed gratings (BSGs) and phase gratings may be employed using the same concepts and equations. A BSG only has two levels of refractive index due to the fact that their grating features (e.g., grating elements and gaps) are typically formed via a single surface etch. A phase grating is similar to a BSG, but consists of lengths of uniform grating of a single pitch, separated by x phase shifts.

Moreover, as discussed above, Equations 7 and 8 describe an analog waveform which can be discretized by the methods shown in U.S. patent application Ser. No. 17/465,403 [Docket No. 3218-008US1]. However, other discretization methods may be employed instead. For example, the binary superimposed grating (BSG) discretization described in I. A. Avrutsky et al., “Design of Widely Tunable Semiconductor Lasers and the Concept of Binary Superimposed Gratings (BSG's)” JSTQE 34 4 1998, may also be applied to laser cavities based on BSGs.

It is to be understood that the disclosure teaches just some examples of the illustrative embodiment and that many variations of the invention can easily be devised by those skilled in the art after reading this disclosure and that the scope of the present invention is to be determined by the following claims.

1. A photonic element comprising:
a bottom cladding;
a top cladding;
a first waveguide that is located between the bottom and top claddings; and
a first multi-wavelength grating that is optically coupled with the first waveguide, wherein the first multi-wavelength grating is characterized by a grating strength and/or phase that varies along a first axis based on a piecewise mathematical function; and
wherein the first waveguide and first multi-wavelength grating collectively enable an output signal at a plurality of wavelengths.

2. The photonic element of claim 1, wherein the first multi-wavelength grating is a windowed sampled grating (WSG).

3. The photonic element of claim 1, wherein the first multi-wavelength grating is a binary superimposed grating (BSG).

4. The photonic element of claim 1, wherein the first multi-wavelength grating is a phase grating (PG).

5. The photonic element of claim 1, wherein the first multi-wavelength grating has a plurality of grating sections each characterized by a grating strength that varies along the first axis based on a subfunction of the piecewise mathematical function, wherein each of the subfunctions is defined as a summation, over the plurality of wavelengths, of an expression that represents a grating at a single wavelength defined in the expression.

6. The photonic element of claim 5, wherein the first multi-wavelength grating includes an additional grating section characterized by a grating phase that varies along the first axis based on a subfunction of the piecewise mathematical function that produces a quarter-wavelength phase shift for each of the plurality of wavelengths.

7. The photonic element of claim 6, wherein the additional grating section defines a summation of corrugation-pitch modulation gratings in which the quarter-wave phase shift is distributed over the grating section.

8. The photonic element of claim 6, wherein the additional grating section is located off-center within the multi-wavelength grating.

9. The photonic element of claim 7, wherein the additional grating section is located off-center within the multi-wavelength grating.

10. The photonic element of claim 1, wherein the wavelengths in the plurality of wavelengths of the output signal define a uniformly spaced frequency comb.

11. The photonic element of claim 1, wherein the wavelengths in the plurality of wavelengths of the output signal define a non-uniformly spaced frequency comb.

12. The photonic element of claim 1, wherein the first multi-wavelength grating is further characterized by a window function that restricts the plurality of wavelength signals to a first wavelength range.

13. The photonic element of claim 1, further comprising a gain-element layer that is optically coupled with the first waveguide, wherein the gain-element layer includes the first multi-wavelength grating.

14. The photonic element of claim 1, wherein the top cladding layer comprises the first multi-wavelength grating.

15. The photonic element of claim 1, wherein the first multiwavelength grating is located below the first waveguide.

16. The photonic element of claim 1, further comprising a gain element that is optically coupled with the first multi-wavelength grating and the first waveguide, wherein the gain element, the first multi-wavelength grating, and the first waveguide collectively define a first laser that generates the plurality of wavelength signals.

17. The photonic element of claim 16, wherein the first waveguide comprises the gain element.

18. The photonic element of claim 17, wherein the gain element includes an active layer that is optically coupled with the first waveguide, wherein the active layer includes at least one quantum element selected from the group consisting of a quantum dot, a quantum dash, a quantum wire, and a quantum well.

19. The photonic element of claim 1, wherein the piecewise mathematical function includes a sinusoid or sinc function.

20. A method for providing a first output signal that includes a plurality of wavelength signals, the method including:
enabling propagation of a first light signal in a first waveguide that is located between a lower cladding and an upper cladding; and
optically coupling the first light signal and a multi-wavelength grating, wherein the first multi-wavelength grating is characterized by a grating strength and/or phase that varies along a first axis based on a piecewise mathematical function, wherein the plurality of wavelength signals is based on the piecewise mathematical function.

21. The method of claim 20, wherein the first multi-wavelength grating is a windowed sampled grating (WSG).

22. The method of claim 20, wherein the first multi-wavelength grating is a binary superimposed grating (BSG).

23. The method of claim 20, wherein the first multi-wavelength grating is a phase grating (PG)

24. The method of claim 20, wherein the first multi-wavelength grating has a plurality of grating sections each characterized by a grating strength that varies along the first axis based on a subfunction of the piecewise mathematical function, wherein each of the subfunctions is defined as a summation, over the plurality of wavelengths, of an expression that represents a grating at a single wavelength defined in the expression.

25. The method of claim 24, wherein the first multi-wavelength grating includes an additional grating section characterized by a grating phase that varies along the first axis based on a subfunction of the piecewise mathematical function that produces a quarter-wavelength phase shift for each of the plurality of wavelengths signals.

26. The method of claim 25, wherein the additional grating section defines a summation of corrugation-pitch modulation gratings in which the quarter-wave phase shift is distributed over the grating section.

27. The method of claim 25 wherein the additional grating section is located off-center within the multi-wavelength grating.

28. The method of claim 26 wherein the additional grating section is located off-center within the multi-wavelength grating.

29. The method of claim 20, wherein the wavelength signals in the plurality of wavelength signals of the output signal define a uniformly spaced frequency comb.

30. The method of claim 20, wherein the wavelength signals in the plurality of wavelength signals of the output signal define a non-uniformly spaced frequency comb.
